(19) United States
(12) Patent Application Publication
(10) Pub. No.: US 2022/0037854 A1
(43) Pub. Date: Feb. 3, 2022

(54) VERTICAL CAVITY SURFACE EMITTING LASER

(71) Applicant: SUMITOMO ELECTRIC INDUSTRIES, LTD., Osaka-shi (JP)

(72) Inventors: Takeshi AOKI, Osaka-shi (JP); Rei TANAKA, Osaka-shi (JP); Yuji KOYAMA, Osaka-shi (JP)

(73) Assignee: SUMITOMO ELECTRIC INDUSTRIES, LTD., Osaka-shi (JP)

(21) Appl. No.: 17/391,091

(22) Filed: Aug. 2, 2021

(30) Foreign Application Priority Data
Aug. 3, 2020 (JP) 2020-131570

(51) Int. Cl. H01S 5/042; H01S 5/183; H01S 5/343

(52) U.S. Cl. CPC H01S 5/04256; H01S 5/18397; H01S 5/18361; H01S 5/18322; H01S 5/18311; H01S 5/34313

(57) ABSTRACT

A vertical cavity surface emitting laser includes a semi-insulating substrate having a major surface including a first area and a second area, an n-type semiconductor layer that is provided on the first area and unprovided on the second area, a semiconductor laminate that is provided on the n-type semiconductor layer, a cathode electrode that is connected to the n-type semiconductor layer, an anode electrode that is connected to a top surface of the semiconductor laminate, and a first conductor that is connected to the anode electrode and extends from the first area to the second area. The semiconductor laminate includes a first distributed Bragg reflector provided on the n-type semiconductor layer, an active layer provided on the first distributed Bragg reflector, and a second distributed Bragg reflector provided on the active layer. The first conductor includes an anode electrode pad provided on the second area.

### CROSS REFERENCE TO RELATED APPLICATIONS

This application claims priority based on Japanese Patent Application No. 2020-131570, filed on Aug. 3, 2020, and the entire contents of the Japanese patent application are incorporated herein by reference.

### TECHNICAL FIELD

The present disclosure relates to a vertical cavity surface emitting laser.

### BACKGROUND

Patent Document 1 (WO 2013/176201) discloses a vertical cavity surface emitting laser in which an n-type semiconductor contact layer, an n-type distributed Bragg reflector (DBR) layer, an insulating film, an insulating layer and an anode electrode pad are provided in this order on a base substrate.

### SUMMARY

The present disclosure provides a vertical cavity surface emitting laser including a semi-insulating substrate having a major surface including a first area and a second area, an n-type semiconductor layer that is provided on the first area and that is not provided on the second area, a semiconductor laminate that is provided on the n-type semiconductor layer, a cathode electrode that is connected to the n-type semiconductor layer, an anode electrode that is connected to a top surface of the semiconductor laminate, and a first conductor that is connected to the anode electrode and extends from the first area to the second area. The semiconductor laminate includes a first distributed Bragg reflector provided on the n-type semiconductor layer, an active layer provided on the first distributed Bragg reflector, and a second distributed Bragg reflector provided on the active layer. The first conductor includes an anode electrode pad provided on the second area.

The present disclosure also provides a vertical cavity surface emitting laser including a semi-insulating substrate having a major surface including a first area, a second area and a third area, the third area being separated from the first area by the second area, an n-type semiconductor layer provided on the first area, the n-type semiconductor layer being not provided on the second area, a semiconductor laminate provided on the n-type semiconductor layer, a cathode electrode connected to the n-type semiconductor layer, an anode electrode connected to a top surface of the semiconductor laminate and a first conductor connected to the anode electrode. The semiconductor laminate includes a first distributed Bragg reflector provided on the n-type semiconductor layer, an active layer provided on the first distributed Bragg reflector, and a second distributed Bragg reflector provided on the active layer. The first conductor extends from the first area to the third area, the first conductor including an anode electrode pad provided on the third area.

### BRIEF DESCRIPTION OF THE DRAWINGS

The foregoing and other purposes, aspects and advantages will be better understood from the following detailed description of a preferred embodiment of the invention with reference to the drawings.

FIG. 1 is a plan view schematically illustrating a vertical cavity surface emitting laser according to a first embodiment.

FIG. 2 is a cross-sectional view taken along line II-II in FIG. 1.

FIG. 3 is a plan view schematically illustrating a vertical cavity surface emitting laser according to a second embodiment.

FIG. 4 is a cross-sectional view taken along line IV-IV in FIG. 3.

FIG. 5 is a plan view schematically illustrating a vertical cavity surface emitting laser according to a third embodiment.

FIG. 6 is a cross-sectional view taken along line VI-VI in FIG. 5.

FIG. 7 is a plan view schematically illustrating a vertical cavity surface emitting laser according to a fourth embodiment.

FIG. 8 is a cross-sectional view taken along line VIII-VIII in FIG. 7.

FIG. 9 is a plan view schematically illustrating a vertical cavity surface emitting laser according to a fifth embodiment.

FIG. 10 is a cross-sectional view taken along line X-X in FIG. 9.

FIG. 11 is a plan view schematically illustrating a vertical cavity surface emitting laser according to a sixth embodiment.

FIG. 12 is a cross-sectional view taken along line XII-XII in FIG. 11.

### DETAILED DESCRIPTION

In a vertical cavity surface emitting laser, a parasitic capacitance occurs between an anode electrode pad and an n-type semiconductor contact layer.

The present disclosure provides a vertical cavity surface emitting laser capable of reducing the parasitic capacitance due to the anode electrode pad.

A vertical cavity surface emitting laser according to an embodiment includes a semi-insulating substrate having a major surface including a first area and a second area, an n-type semiconductor layer that is provided on the first area and that is not provided on the second area, a semiconductor laminate that is provided on the n-type semiconductor layer, a cathode electrode that is connected to the n-type semiconductor layer, an anode electrode that is connected to a top surface of the semiconductor laminate, and a first conductor that is connected to the anode electrode and extends from the first area to the second area. The semiconductor laminate includes a first distributed Bragg reflector provided on the n-type semiconductor layer, an active layer provided on the first distributed Bragg reflector, and a second distributed Bragg reflector provided on the active layer. The first conductor includes an anode electrode pad provided on the second area.

According to the vertical cavity surface emitting laser, the n-type semiconductor layer is not located below the anode electrode pad. Therefore, the parasitic capacitance between the anode electrode pad and the n-type semiconductor layer can be reduced.

A second area may include a recess. The recess may be formed by etching the n-type semiconductor layer followed by etching the major surface of the semi-insulating substrate. In this instance, the possibility that the n-type semiconductor layer remains on the second area can be reduced.

The vertical cavity surface emitting laser may further include a second conductor connected to the cathode electrode. The second conductor may include a cathode electrode pad provided on the second area. This allows the cathode electrode pad to be disposed away from the cathode electrode.

The first conductor may include a wiring conductor between the anode electrode and the anode electrode pad. The wiring conductor may include a portion that is provided on the second area and extends along the major surface. In this instance, the n-type semiconductor layer is also not located below the portion of the wiring conductor. Therefore, the parasitic capacitance between the portion of the wiring conductor and the n-type semiconductor layer can be reduced.

The second area may reach an edge of the major surface. In this instance, the space around the anode electrode pad can be widened.

A vertical cavity surface emitting laser according to another embodiment includes a semi-insulating substrate having a major surface including a first area, a second area and a third area, the third area being separated from the first area by the second area, an n-type semiconductor layer provided on the first area, the n-type semiconductor layer being not provided on the second area, a semiconductor laminate provided on the n-type semiconductor layer, a cathode electrode connected to the n-type semiconductor layer, an anode electrode connected to a top surface of the semiconductor laminate and a first conductor connected to the anode electrode. The semiconductor laminate includes a first distributed Bragg reflector provided on the n-type semiconductor layer, an active layer provided on the first distributed Bragg reflector, and a second distributed Bragg reflector provided on the active layer. The first conductor extends from the first area to the third area, the first conductor including an anode electrode pad provided on the third area.

According to the vertical cavity surface emitting laser, the n-type semiconductor layer is not provided on the second area. Therefore, the parasitic capacitance between the anode electrode pad on the third area and the n-type semiconductor layer on the first area can be reduced.

The semiconductor laminate may be a first semiconductor laminate. The n-type semiconductor layer and a second semiconductor laminate may be provided on the third area, the second semiconductor laminate being provided between the n-type semiconductor layer and the anode electrode pad. In this case, the n-type semiconductor layer and the second semiconductor laminate on the third area is electrically insulated from the n-type semiconductor layer on the first area.

A height from the major surface to a top surface of the second semiconductor laminate may be same as a height from the major surface to the top surface of the first semiconductor laminate. In this case, the top surface of the first semiconductor laminate and the top surface of the second semiconductor laminate can be easily mounted on a surface of another member.

### DETAILS OF EMBODIMENTS OF THE PRESENT DISCLOSURE

Hereinafter, embodiments according to the present disclosure will be described in detail with reference to the accompanying drawings. In the description of the drawings, like or corresponding elements are denoted by like reference numerals and redundant descriptions thereof will be omitted.

### First Embodiment

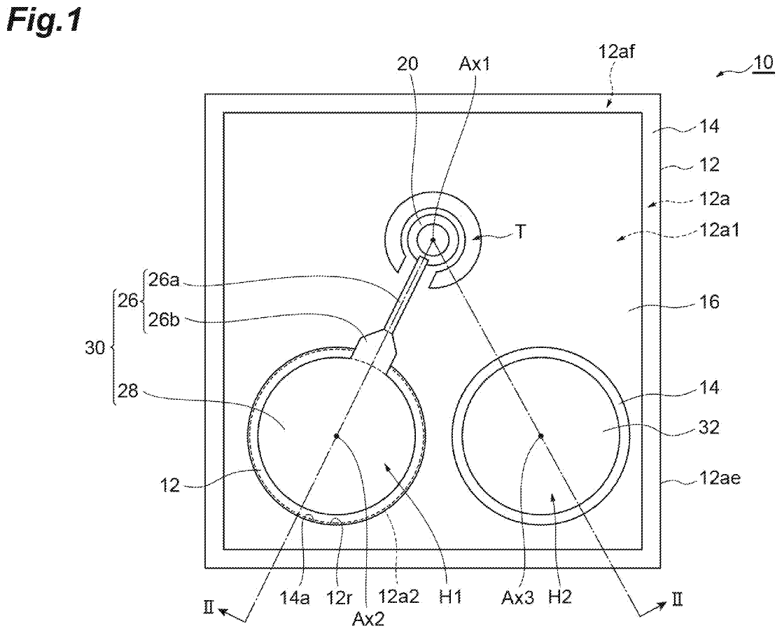

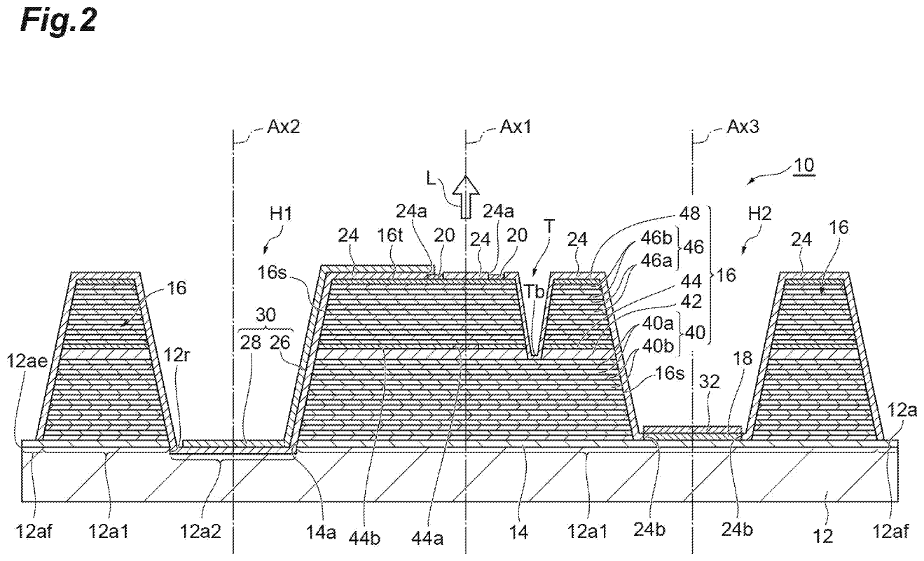

FIG. 1 is a plan view schematically illustrating a vertical cavity surface emitting laser according to the first embodiment. FIG. 2 is a cross-sectional view taken along line II-II in FIG. 1. A vertical cavity surface emitting laser (VCSEL) 10 illustrated in FIGS. 1 and 2 emits a laser light L in a direction along an axis Ax1. Vertical cavity surface emitting laser 10 includes a semi-insulating substrate 12, an n-type semiconductor layer 14, a semiconductor laminate 16 (a first semiconductor laminate), a cathode electrode 18, an anode electrode 20, and a first conductor 30.

Semi-insulating substrate 12 has a major surface 12a that intersects axis Ax1. Major surface 12a includes a first area 12a1 and a second area 12a2. Second area 12a2 is a circular area, for example. First area 12a1 is, for example, a rectangular area surrounding second area 12a2. Major surface 12a may have a frame-like area 12af surrounding first area 12a1 and second area 12a2. Frame-like area 12af extends along an edge 12ae of major surface 12a. Frame-like area 12af is a scribe region for cutting between adjacent vertical cavity surface emitting lasers 10 when a plurality of vertical cavity surface emitting lasers 10 are produced from a single substrate. Second area 12a2 may include a recess 12r. Recess 12r is formed over the entire second area 12a2, for example. Recess 12r is formed by photolithography and etching, for example. A depth of recess 12r is 1 μm or more and 3 μm or less, for example. A carrier density of semi-insulating substrate 12 is 1×10¹⁵ cm⁻³ or less, for example. A resistivity of semi-insulating substrate 12 is 1×10⁷ Ω·cm or more, for example. The resistivity of semi-insulating substrate 12 can be measured by a four-terminal method, for example. An etch pit density (EPD) of semi-insulating substrate 12 is equal to or less than 2000 cm⁻², for example, in order to improve a reliability of the lasers. Semi-insulating substrate 12 may be a III-V group compound semiconductor substrate such as GaAs substrate, for example. Semi-insulating substrate 12 may include a base substrate and a semi-insulating semiconductor layer provided on the base substrate. In this case, a top surface of the semi-insulating semiconductor layer is defined as major surface 12a.

N-type semiconductor layer 14 is not provided on second area 12a2, but provided on first area 12a1. N-type semiconductor layer 14 is provided over the entire first area 12a1, for example. N-type semiconductor layer 14 is not provided on frame-like area 12af. N-type semiconductor layer 14 may have an opening 14a provided on second area 12a2. Opening 14a may have the same shape as second area 12a2 and recess 12r. Opening 14a is formed by photolithography and etching, for example. A thickness of n-type semiconductor layer 14 is 1 μm or more and 3 μm or less, for example. For example, when opening 14a is formed by the etching, by using a thick n-type semiconductor layer 14, the n-type semiconductor layer 14 can be reliably left on first area 12a1 even if a depth of the etching varies. In addition, by over-etching n-type semiconductor layer 14 so that n-type semiconductor layer 14 does not remain on second area 12a2, recess 12r is formed on second area 12a2. N-type semiconductor layer 14 includes an n-type semiconductor contact layer, for example. N-type semiconductor layer 14 is a GaAs layer, for example. A dopant concentration of n-type semiconductor layer 14 is 2×10¹⁸ cm⁻³ or more, for example. Examples of n-type dopants include Si.

Semiconductor laminate 16 is provided on n-type semiconductor layer 14. Semiconductor laminate 16 is not provided on second area 12a2, but provided on first area 12a1. Semiconductor laminate 16 includes a first distributed Bragg reflector 40 provided on n-type semiconductor layer 14, an active layer 42 provided on first distributed Bragg reflector 40, and a second distributed Bragg reflector 46 provided on active layer 42.

First distributed Bragg reflector 40 includes first semiconductor layers 40a and second semiconductor layers 40b. Each first semiconductor layer 40a and each second semiconductor layer 40b are alternately laminated along axis Ax1. First semiconductor layers 40a and second semiconductor layers 40b are n-type III-V group compound semiconductor layers (n-type AlGaAs layers), for example, and have different refractive indexes (Al compositions) from each other. The number of the pairs of first semiconductor layer 40a and second semiconductor layer 40b is 35 or more and 45 or less, for example.

Active layer 42 may include a multiple quantum well structure and a pair of spacers sandwiching the multiple quantum well structure. The multiple quantum well structure includes, for example, InGaAs layers and AlGaAs layers. Each InGaAs layer and each AlGaAs layer are alternately laminated.

Second distributed Bragg reflector 46 includes first semiconductor layers 46a and second semiconductor layers 46b. Each first semiconductor layer 46a and each second semiconductor layer 46b are alternately laminated along axis Ax1. First semiconductor layers 46a and second semiconductor layers 46b are p-type group III-V compounds semiconductor layers (p-type AlGaAs layers), for example, and have different refractive indexes (Al compositions) from each other. Examples of p-type dopants include C (carbon). The number of the pairs of first semiconductor layers 46a and second semiconductor layers 46b is 20 or more, for example.

A current confinement layer 44 is provided between active layer 42 and second distributed Bragg reflector 46. Current confinement layer 44 includes an aperture 44a through which axis Ax1 passes and a current blocking layer 44b surrounding aperture 44a. Aperture 44a is a semiconductor layer, for example. Current blocking layer 44b is an oxide layer, for example.

A p-type semiconductor layer 48 is provided on second distributed Bragg reflector 46. A top surface of p-type semiconductor layer 48 provides a top surface 16t of semiconductor laminate 16. P-type semiconductor layer 48 includes a p-type semiconductor contact layer, for example. A thickness of p-type semiconductor layer 48 is 100 nm or more, for example. The p-type semiconductor contact layer is an AlGaAs layer, for example. A dopant concentration of p-type semiconductor layer 48 is 2×10¹⁸ cm⁻³ or more, for example. A cap layer such as a GaAs layer may be provided on the p-type semiconductor contact layer.

Anode electrode 20 is connected to top surface 16t of semiconductor laminate 16. Anode electrode 20 is provided so as to surround axis Ax1. Anode electrode 20 has, for example, a ring-shape when viewed from a direction along axis Ax1. A trench T is provided on top surface 16t of semiconductor laminate 16 so as to surround anode electrode 20. Since trench T is away from anode electrode 20, top surface 16t of semiconductor laminate 16 is located between trench T and anode electrode 20. Trench T has, for example, a partially broken ring-shape when viewed from the direction along axis Ax1. A bottom Tb of trench T may reach active layer 42. Trench T is formed by photolithography and etching, for example. After trench T is formed, oxidation treatment is performed to oxidize the same semiconductor as that of aperture 44a to form current blocking layer 44b.

Top surface 16t of semiconductor laminate 16 has a first depressed portion H1 and a second depressed portion H2. First depressed portion H1 and second depressed portion H2 are away from trench T. First depressed portion H1 is provided on second area 12a2. Second depressed portion H2 is provided on first area 12a1. A bottom of first depressed portion H1 reaches semi-insulating substrate 12. A bottom of second depressed portion H2 reaches n-type semiconductor layer 14. First depressed portion H1 and second depressed portion H2 are separated from each other. First depressed portion H1 has, for example, a circular shape centered on axis Ax2 when viewed from a direction along axis Ax2. Axis Ax2 is parallel to axis Ax1. Second depressed portion H2 has, for example, a circular shape centered on an axis Ax3 when viewed from a direction along axis Ax3. Axis Ax3 is parallel to axis Ax1. Each of first depressed portion H1 and second depressed portion H2 is defined by a side 16s of semiconductor laminate 16. First depressed portion H1 and second depressed portion H2 are formed by photolithography and etching, for example.

An insulating layer 24 is provided on top surface 16t and side surface 16s of semiconductor laminate 16. Insulating layer 24 extends from first area 12a1 to second area 12a2 on major surface 12a. That is, insulating layer 24 is also provided on the bottom of first depressed portion H1. Insulating layer 24 has an opening 24a on top surface 16t. Anode electrode 20 is connected to top surface 16t of semiconductor laminate 16 through opening 24a. Insulating layer 24 has an opening 24b on n-type semiconductor layer 14 at the bottom of second depressed portion H2. Cathode electrode 18 is connected to n-type semiconductor layer 14 through opening 24b. Insulating layer 24 may be a silicon nitride layer such as a SiN layer. In FIG. 1, insulating layer 24 is omitted.

First conductor 30 is connected to anode electrode 20 and extends, on major surface 12a, from first area 12a1 to second area 12a2. First conductor 30 is provided on insulating layer 24. First conductor 30 includes an anode electrode pad 28 provided on second area 12a2. Anode electrode pad 28 extends along major surface 12a. Anode electrode pad 28 has, for example, a circular shape centered on axis Ax2 when viewed from the direction along axis Ax2. A diameter of anode electrode pad 28 is 40 μm or more, for example.

First conductor 30 includes a wiring conductor 26 between anode electrode 20 and anode electrode pad 28. Wiring conductor 26 extends on insulating layer 24 along a direction connecting anode electrode 20 and anode electrode pad 28 (for example, a direction connecting axis Ax1 and axis Ax2). Wiring conductor 26 includes a first portion 26a connected to anode electrode 20, and a second portion 26b between first portion 26a and anode electrode pad 28. The width of second portion 26b is larger than the width of first portion 26a. Second portion 26b has a tapered portion whose width widens as approaching from first portion 26a toward anode electrode pad 28, and a wide portion between the tapered portion and anode electrode pad 28. The wide portion of second part 26b is provided so as to cover a bent portion formed by side surface 16s of semiconductor laminate 16 and major surface 12a of semi-insulating substrate 12. A larger width of second portion 26b reduce the possibility of a disconnection in wiring conductor 26 caused by the bent portion.

Cathode electrode 18 is connected to n-type semiconductor layer 14. Cathode electrode 18 is located at the bottom of second depressed portion H2 and is provided on n-type semiconductor layer 14. Cathode electrode 18 has, for example, a circular shape centered on axis Ax3 when viewed from the direction along axis Ax3. A cathode electrode pad 32 is provided on cathode electrode 18. Cathode electrode pad 32 extends along major surface 12a. Cathode electrode pad 32 has, for example, a circular shape centered on axis Ax3. A diameter of cathode electrode pad 32 is 40 μm or more, for example.

According to vertical cavity surface emitting laser 10, n-type semiconductor layer 14 and semiconductor laminate 16 are not located below anode electrode pad 28. As a result, only insulating layer 24 is interposed between anode electrode pad 28 and semi-insulating substrate 12. Thus, the parasitic capacitance between anode electrode pad 28 and n-type semiconductor layer 14 can be reduced. This allows modulation bandwidth of vertical cavity surface emitting laser 10 to be increased.

A parasitic capacitance caused by the electrode pad and a wiring line of vertical cavity surface emitting laser 10 according to one embodiment is 70 fF. The parasitic capacitance caused by the electrode pad and the wiring line can be calculated by measuring a frequency response (S parameter) of a high-frequency modulation in the vertical cavity surface emitting laser and by fitting it using an equivalent circuit model. Examples of the equivalent circuit model are presented in a literature, Philip Wolf, et al., “Extraction and analysis of high-frequency response and impedance of 980-nm VCSELs as a function of temperature and oxide aperture diameter”, Proc. SPIE 9381, Vertical-Cavity Surface-Emitting Lasers XIX, 93810H (4 Mar. 2015). On the other hand, a parasitic capacitance of a vertical cavity surface emitting laser according to a comparative example in which an anode electrode pad is disposed on a top surface 16t of a semiconductor laminate 16 is 130 fF. In the vertical cavity surface emitting laser according to the comparative example, the semiconductor laminate below the anode electrode pad is semi-insulated by proton implantation.

According to vertical cavity surface emitting laser 10, second area 12a2 includes recess 12r. Recess 12r is formed by etching n-type semiconductor layer 14 to form opening 14a followed by etching major surface 12a of semi-insulating substrate 12. Therefore, the possibility that n-type semiconductor layer 14 remains on second area 12a2 can be reduced.

### Second Embodiment

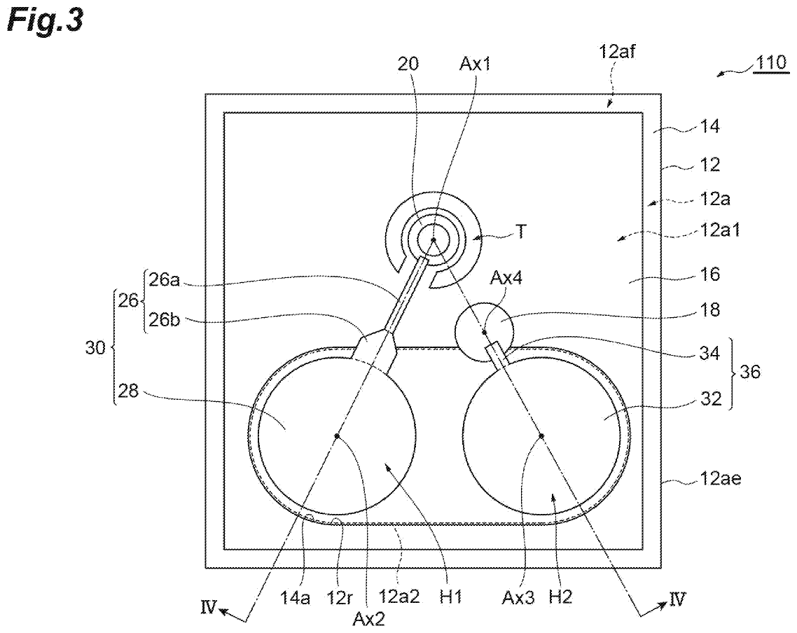

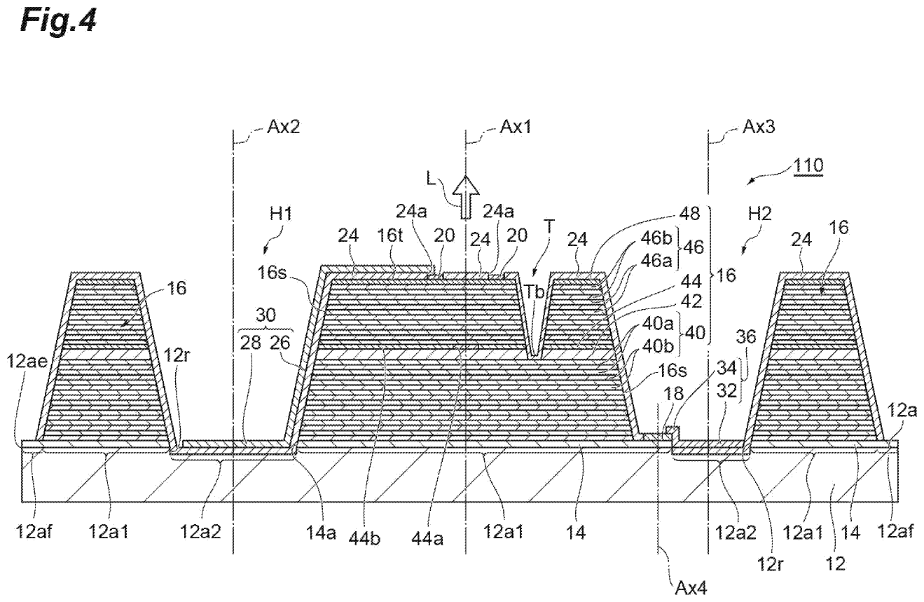

FIG. 3 is a plan view schematically illustrating a vertical cavity surface emitting laser according to the second embodiment. FIG. 4 is a cross-sectional view taken along line IV-IV in FIG. 3. A vertical cavity surface emitting laser 110 illustrated in FIGS. 3 and 4 has the same configuration as vertical cavity surface emitting laser 10 except that the range of a second area 12a2 (recess 12r) is different and a second conductor 36 is provided instead of a cathode electrode pad 32.

In this embodiment, second area 12a2 (recess 12r) extends from a portion below an anode electrode pad 28 to a portion below cathode electrode pad 32. Cathode electrode pad 32 is disposed on an insulating layer 24 provided on recess 12r.

Second conductor 36 includes cathode electrode pad 32 and a wiring conductor 34 between a cathode electrode 18 and cathode electrode pad 32. Cathode electrode 18 has, for example, a circular shape centered on an axis Ax4 when viewed from a direction along axis Ax4. Axis Ax4 is parallel to an axis Ax3. The diameter of cathode electrode 18 is smaller than the diameter of cathode electrode pad 32. Wiring conductor 34 extends along a direction connecting cathode electrode 18 and cathode electrode pad 32 (for example, a direction connecting axis Ax3 and axis Ax4).

According to vertical cavity surface emitting laser 110, the same effect as that of vertical cavity surface emitting laser 10 can be obtained. In addition, in vertical cavity surface emitting laser 110, cathode electrode pad 32 can be separated from cathode electrode 18. Therefore, the size of cathode electrode 18 can be reduced while the size of cathode electrode pad 32 is kept large.

### Third Embodiment

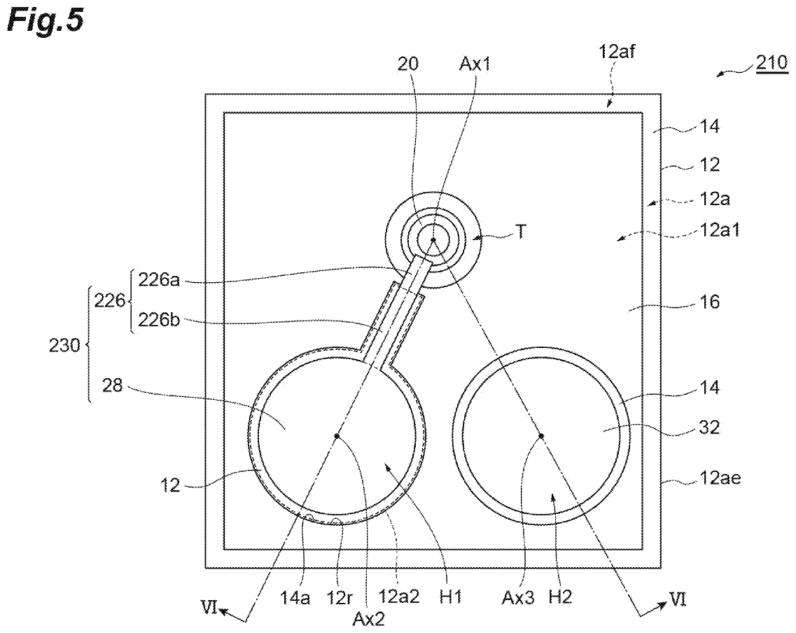

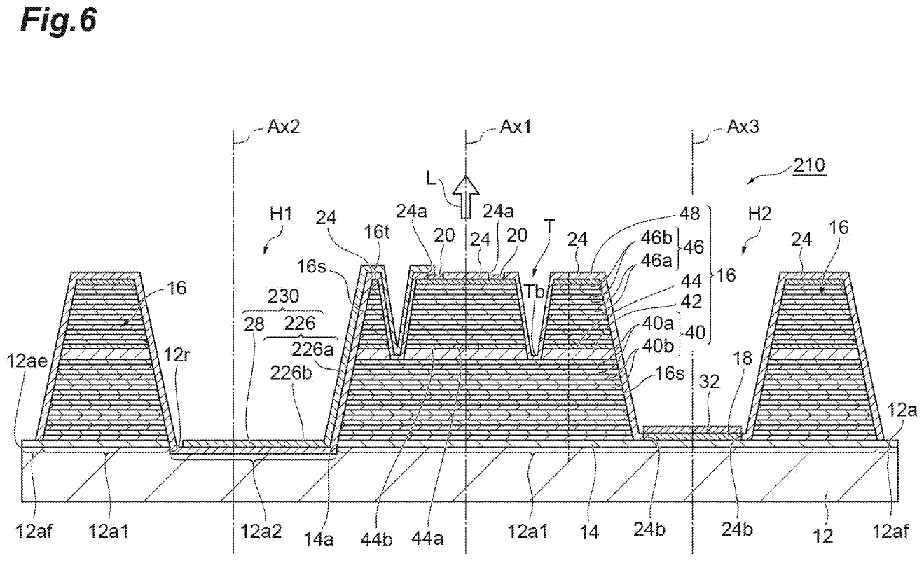

FIG. 5 is a plan view schematically illustrating a vertical cavity surface emitting laser according to the third embodiment. FIG. 6 is a cross-sectional view taken along line VI-VI in FIG. 5. A vertical cavity surface emitting laser 210 illustrated in FIGS. 5 and 6 has the same configuration as vertical cavity surface emitting laser 10 except that the range of a second area 12a2 (recess 12r) is different and a first conductor 230 is provided instead of a first conductor 30.

In this embodiment, second area 12a2 (recess 12r) includes a portion located below an anode electrode pad 28 and a portion extending from anode electrode pad 28 toward an anode electrode 20.

First conductor 230 has the same configuration as a first conductor 30 except that first conductor 230 includes a wiring conductor 226 instead of a wiring conductor 26. Wiring conductor 226 extends along a direction connecting anode electrode 20 and anode electrode pad 28 (for example, a direction connecting an axis Ax1 and an axis Ax2). Wiring conductor 226 includes a first portion 226a connected to anode electrode 20, and a second portion 226b between first portion 226a and anode electrode pad 28. First portion 226a is provided on a first area 12a1. Second portion 226b is provided on second area 12a2 and extends along a major surface 12a of a semi-insulating substrate 12. Second part 226b is provided on an insulating layer 24 provided on recess 12r. In a direction along major surface 12a, the length of second portion 226b is greater than the length of first portion 226a.

According to vertical cavity surface emitting laser 210, the same effect as that of vertical cavity surface emitting laser 10 can be obtained. Further, in vertical cavity surface emitting laser 210, an n-type semiconductor layer 14 is not located below second part 226b of wiring conductor 226. Therefore, the parasitic capacitance between second part 226b of wiring conductor 226 and n-type semiconductor layer 14 can be reduced.

### Fourth Embodiment

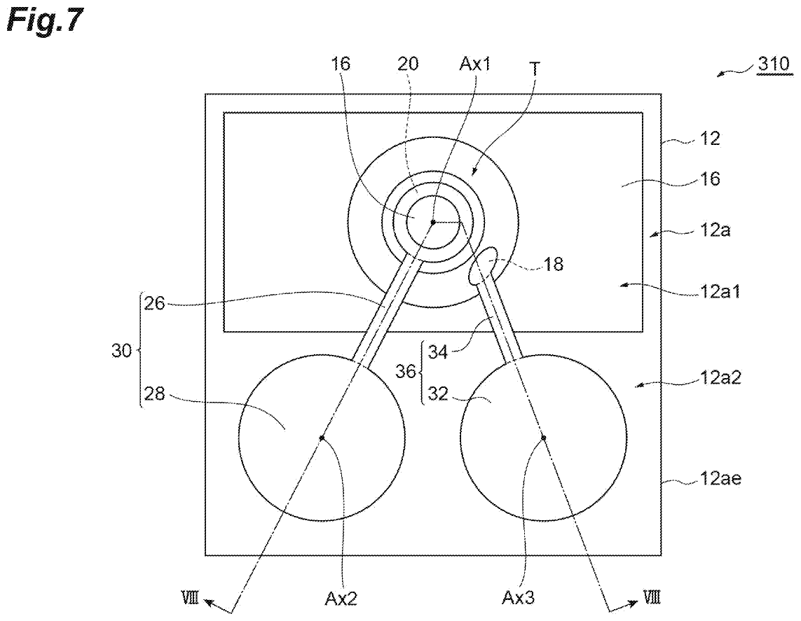

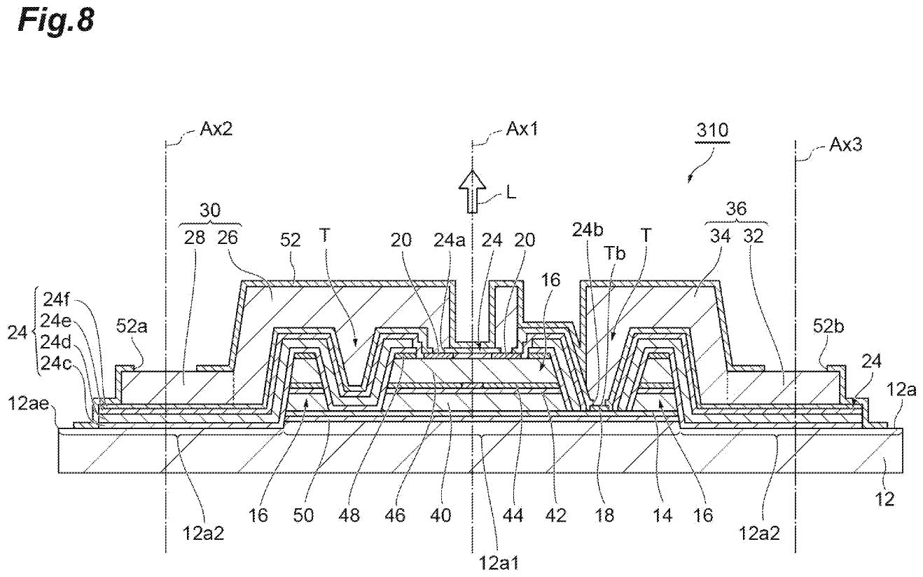

FIG. 7 is a plan view schematically illustrating a vertical cavity surface emitting laser according to the fourth embodiment. FIG. 8 is a cross-sectional view taken along line VIII-VIII in FIG. 7. A vertical cavity surface emitting laser 310 illustrated in FIGS. 7 and 8 has a configuration similar to vertical cavity surface emitting laser 110 in FIG. 3. The main differences are described below.

According to vertical cavity surface emitting laser 310, a major surface 12a of a semi-insulating substrate 12 includes a second area 12a2 (recess 12r) which surrounds a first area 12a1. Major surface 12a has no frame-like area 12af. Second area 12a2 includes a scribe region. Scribe region extends along an edge 12ae of major surface 12a. Second area 12a2 extends from the peripheries of anode electrode pad 28 and cathode electrode pad 32 to edge 12ae of major surface 12a. Therefore, an n-type semiconductor layer 14 and a semiconductor laminate 16 are not provided in a large area around anode electrode pad 28 and cathode electrode pad 32.

An opening 24b of an insulating layer 24 is provided at a bottom Tb of a trench T. At bottom Tb of trench T, a cathode electrode 18 is connected to n-type semiconductor layer 14 through opening 24b. Insulating layer 24 includes a first insulating layer 24c, a second insulating layer 24d, a third insulating layer 24e and a fourth insulating layer 24f that are provided in this order on a semi-insulating substrate 12. Each of first insulating layer 24c, second insulating layer 24d, third insulating layer 24e and fourth insulating layer 24f may be a silicon nitride layer such as a SiN layer.

A third distributed Bragg reflector 50 is disposed between first area 12a1 and n-type semiconductor layer 14. Third distributed Bragg reflector 50 includes first semiconductor layers and second semiconductor layers. Each first semiconductor layer and each second semiconductor layer are alternately laminated along an axis Ax1. For example, the first semiconductor layers and the second semiconductor layers are i-type group III-V compound semiconductor layers and have different refractive indexes from each other.

Anode electrode pad 28 is in contact with insulating layer 24. A wiring conductor 26 extends from an edge of anode electrode pad 28 onto an anode electrode 20. Cathode electrode pad 32 is in contact with insulating layer 24. A wiring conductor 34 extends from an edge of cathode electrode pad 32 onto cathode electrode 18.

An insulating layer 52 is provided on a first conductor 30 and a second conductor 36. Insulating layer 52 has an opening 52a provided on anode electrode pad 28 and an opening 52b provided on cathode electrode pad 32. A wire is connected to anode electrode pad 28 in opening 52a. A wire is connected to cathode electrode pad 32 in opening 52b. In FIG. 7, insulating layer 24 and insulating layer 52 are omitted.

According to vertical cavity surface emitting laser 310, the same effect as that of vertical cavity surface emitting laser 110 in FIG. 3 can be obtained. In addition, since second area 12a2 reaches edge 12ae of major surface 12a, the space around anode electrode pad 28 and cathode electrode pad 32 is widened. Therefore, there are few obstacles at the time of wire bonding to anode electrode pad 28 and cathode electrode pad 32. Further, when semiconductor laminate 16 on second area 12a2 is removed by etching, the area to be etched is larger, so that etching rate becomes larger.

In a vertical cavity surface emitting laser according to a comparative example in which an anode electrode pad is disposed on a top surface 16t of a semiconductor laminate 16, a cut-off frequency in the 3-dB band is 16.8 GHz. In the vertical cavity surface emitting laser according to the comparative example, the semiconductor laminate below the anode electrode pad is semi-insulated by proton implantation. On the other hand, in vertical cavity surface emitting laser 310 according to the embodiment, a cutoff frequency in the 3 dB band is estimated to be about 17.8 GHz.

### Fifth Embodiment

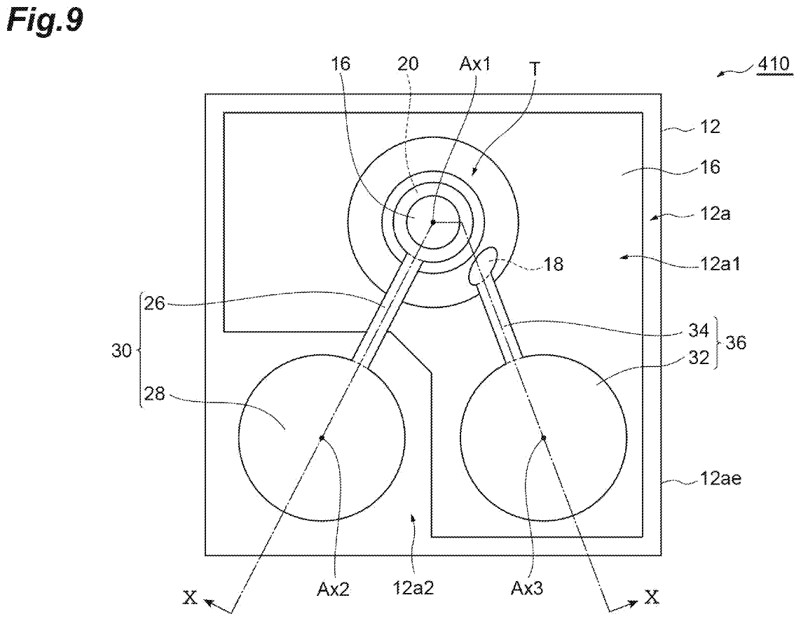

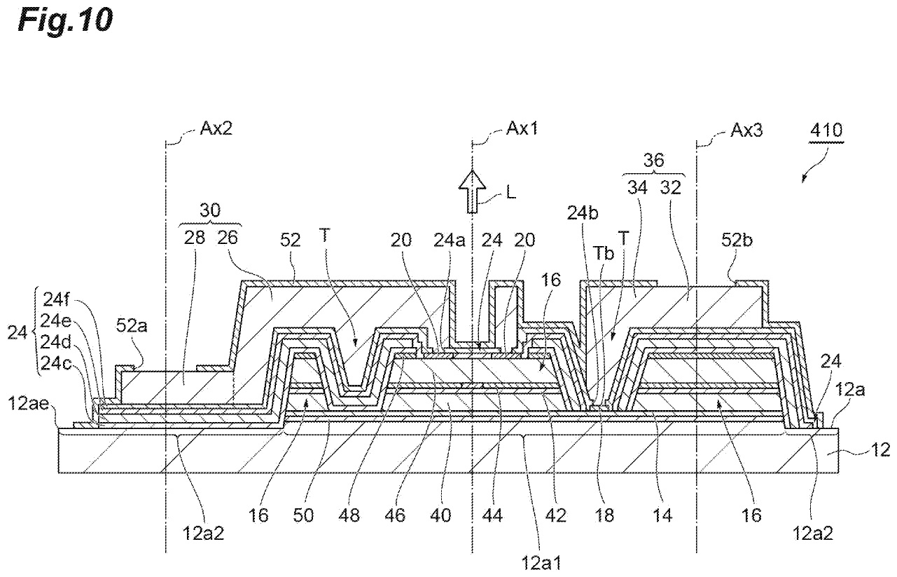

FIG. 9 is a plan view schematically illustrating a vertical cavity surface emitting laser according to the fifth embodiment. FIG. 10 is a cross-sectional view taken along line X-X in FIG. 9. A vertical cavity surface emitting laser 410 illustrated in FIGS. 9 and 10 has the same configuration as vertical cavity surface emitting laser 310 except that the range of a second area 12a2 (recess 12r) is different and a cathode electrode pad 32 is provided on a first area 12a1.

In this embodiment, cathode electrode pad 32 is located on an insulating layer 24 provided on a top surface 16t of a semiconductor laminate 16.

According to vertical cavity surface emitting laser 410, the same effect as that of vertical cavity surface emitting laser 310 can be obtained.

The embodiments of the present disclosure have been described in detail above. However, the present disclosure is not limited to the above embodiments. Each component of each embodiment may be arbitrarily combined.

In vertical cavity surface emitting lasers 10, 110 and 210, cathode electrode pad 32 may be provided on first area 12a1, so that cathode electrode pad 32 is located on insulating layer 24 provided on top surface 16t of semiconductor laminate 16.

While the principles of the present invention have been illustrated and described in preferred embodiments, it will be appreciated by those skilled in the art that the invention may be modified in arrangement and detail without departing from such principles. The present invention is not limited to the specific configurations disclosed in this embodiment. Accordingly, it is claimed that all modifications and changes come from the scope of the claims and their spirit.

### Sixth Embodiment

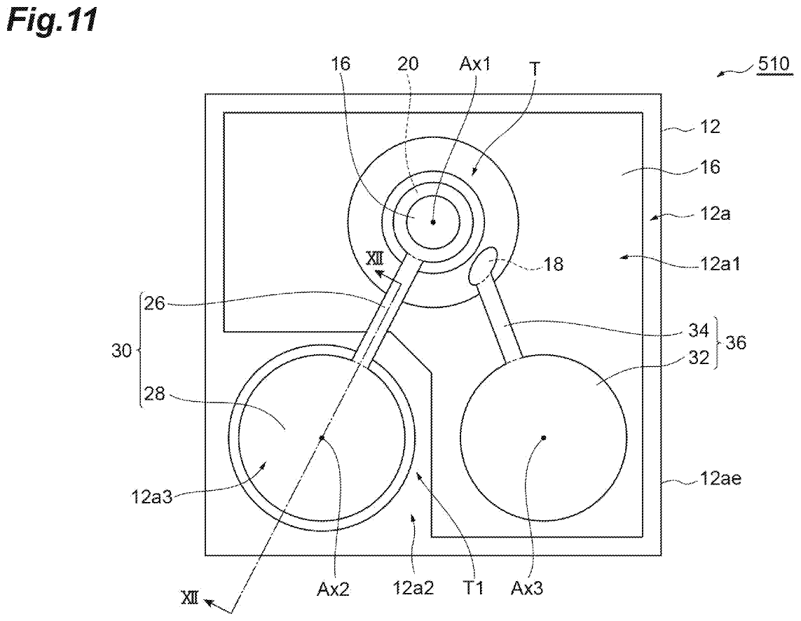

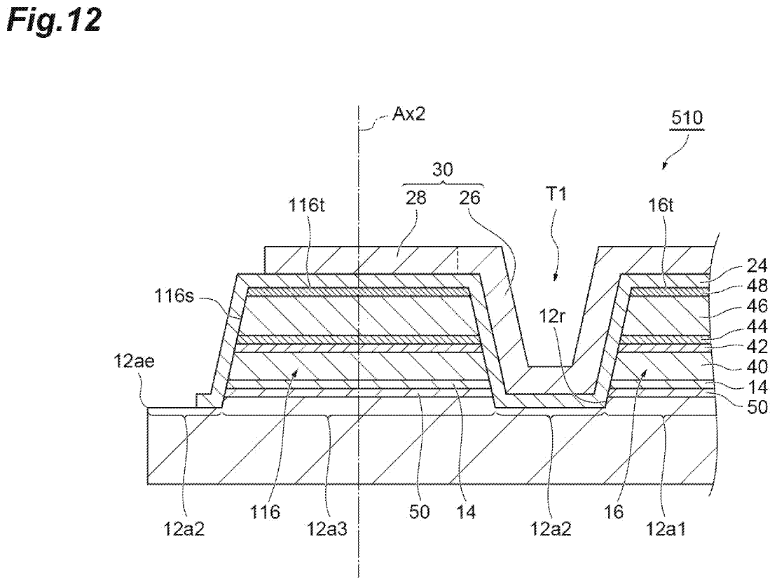

FIG. 11 is a plan view schematically illustrating a vertical cavity surface emitting laser according to a sixth embodiment. FIG. 12 is a cross-sectional view taken along line XII-XII in FIG. 11. A vertical cavity surface emitting laser 510 illustrated in FIGS. 11 and 12 has the same configuration as vertical cavity surface emitting laser 410 except that n-type semiconductor layer 14 and a semiconductor laminate 16 (a second semiconductor laminate) are provided between major surface 12a of semi-insulating substrate 12 and anode electrode pad 28.

In this embodiment, major surface 12a of semi-insulating substrate 12 includes first area 12a1, second area 12a2 and a third area 12a3. Third area 12a3 is separated from first area 12a1 by second area 12a2. The shortest distance between first area 12a1 and third area 12a3 may be 1 μm or more. Third area 12a3 is, for example, a circular area. Second area 12a2 surrounds first area 12a1 and third area 12a3, respectively. Second area 12a2 may include recess 12r.

First conductor 30 extends from first area 12a1 through second area 12a2 to third area 12a3. First conductor 30 includes anode electrode pad 28 provided on third area 12a3. First conductor 30 may be provided on insulating layer 24 extending from first area 12a1 through second area 12a2 to third area 12a3 on main surface 12a. Insulating layer 24 may be in contact with second area 12a2.

In this embodiment, n-type semiconductor layer 14 and semiconductor laminate 116 are provided on third area 12a3. Semiconductor laminate 116 is disposed between n-type semiconductor layer 14 and anode electrode pad 28. N-type semiconductor layer 14 and semiconductor laminate 116 are not provided on second area 12a2. That is, a trench T2 is formed on second area 12a2 between semiconductor laminate 16 and semiconductor laminate 116. The height from major surface 12a of semi-insulating substrate 12 to top surface 116t of semiconductor laminate 116 may be the same as the height from major surface 12a of semi-insulating substrate 12 to top surface 16t of semiconductor laminate 16. Semiconductor laminate 116 may have the same layer structure as semiconductor laminate 16. Insulating layer 24 extends along top surface 116t and side surfaces 116s of semiconductor laminate 116 on third area 12a3. N-type semiconductor layer 14 and semiconductor laminate 116 may not be provided on third area 12a3. In this case, vertical cavity surface emitting laser 510 has the same structure as vertical cavity surface emitting laser 410.

According to vertical cavity surface emitting laser 510, n-type semiconductor layer 14 is not provided on second area 12a2. Therefore, the parasitic capacitance between anode electrode pad 28 on third area 12a3 and n-type semiconductor layer 14 on first area 12a1 can be reduced.

When n-type semiconductor layer 14 and semiconductor laminate 116 are provided on third area 12a3, n-type semiconductor layer 14 and second semiconductor laminate 116 on third area 12a3 are electrically insulated from n-type semiconductor layer 14 on first area 12a1.

The height from major surface 12a of semi-insulating substrate 12 to top surface 116t of semiconductor laminate 116 may be the same as the height from major surface 12a of semi-insulating substrate 12 to top surface 16t of semiconductor laminate 16. In this case, top surface 16t of semiconductor laminate 16 and top surface 116t of second semiconductor laminate 116 can be easily mounted on a surface of another member. For example, vertical cavity surface emitting laser 510 is less inclined with respect to the surface of another member at the time of mounting.

What is claimed is:

1. A vertical cavity surface emitting laser comprising:
a semi-insulating substrate having a major surface including a first area and a second area;
an n-type semiconductor layer provided on the first area, the n-type semiconductor layer being not provided on the second area;
a semiconductor laminate provided on the n-type semiconductor layer, the semiconductor laminate including a first distributed Bragg reflector provided on the n-type semiconductor layer, an active layer provided on the first distributed Bragg reflector, and a second distributed Bragg reflector provided on the active layer;
a cathode electrode connected to the n-type semiconductor layer;
an anode electrode connected to a top surface of the semiconductor laminate; and
a first conductor connected to the anode electrode, the first conductor extending from the first area to the second area, the first conductor including an anode electrode pad provided on the second area.

2. The vertical cavity surface emitting laser according to claim 1, wherein the second area includes a recess.

3. The vertical cavity surface emitting laser according to claim 1, further comprising:
a second conductor connected to the cathode electrode,
wherein the second conductor includes a cathode electrode pad provided on the second area.

4. The vertical cavity surface emitting laser according to claim 1, wherein the first conductor includes a wiring conductor between the anode electrode and the anode electrode pad, and the wiring conductor includes a portion provided on the second area, the portion extending along the major surface.

5. The vertical cavity surface emitting laser according to claim 1, wherein the second area reaches an edge of the major surface.

6. The vertical cavity surface emitting laser according to claim 2, wherein a depth of the recess is 1 μm or more and 3 μm or less.

7. The vertical cavity surface emitting laser according to claim 1, wherein the top surface of the semiconductor laminate comprises a depressed portion on the second area, the depressed portion having a bottom reaching the semi-insulating substrate.

8. The vertical cavity surface emitting laser according to claim 1, further comprising an insulating layer extending from the first area to the second area on the major surface, the first conductor provided on the insulating layer.

9. The vertical cavity surface emitting laser according to claim 8, wherein only the insulating layer is interposed between the anode electrode pad and the semi-insulating substrate.

10. The vertical cavity surface emitting laser according to claim 1, wherein the first conductor includes a wiring conductor between the anode electrode and the anode electrode pad, and the wiring conductor includes a first portion connected to the anode electrode and a second portion between the first portion and the anode electrode pad, wherein a width of the second portion is larger than a width of first portion.

11. The vertical cavity surface emitting laser according to claim 10, wherein the second portion covers a bent portion formed by a side surface of the semiconductor laminate and the major surface.

12. The vertical cavity surface emitting laser according to claim 1, wherein the first conductor includes a wiring conductor between the anode electrode and the anode electrode pad, and the wiring conductor includes a first portion connected to the anode electrode and a second portion between the first portion and the anode electrode pad, wherein a length of the second portion is greater than a length of first portion in a direction along the major surface.

13. A vertical cavity surface emitting laser comprising:
a semi-insulating substrate having a major surface including a first area, a second area and a third area, the third area being separated from the first area by the second area;
an n-type semiconductor layer provided on the first area, the n-type semiconductor layer being not provided on the second area;
a semiconductor laminate provided on the n-type semiconductor layer, the semiconductor laminate including a first distributed Bragg reflector provided on the n-type semiconductor layer, an active layer provided on the first distributed Bragg reflector, and a second distributed Bragg reflector provided on the active layer;
a cathode electrode connected to the n-type semiconductor layer;
an anode electrode connected to a top surface of the semiconductor laminate; and
a first conductor connected to the anode electrode, the first conductor extending from the first area to the third area, the first conductor including an anode electrode pad provided on the third area.

14. The vertical cavity surface emitting laser according to claim 13, wherein the semiconductor laminate is a first semiconductor laminate, wherein the n-type semiconductor layer and a second semiconductor laminate are provided on the third area, the second semiconductor laminate being provided between the n-type semiconductor layer and the anode electrode pad.

15. The vertical cavity surface emitting laser according to claim 14, wherein a height from the major surface to a top surface of the second semiconductor laminate is same as a height from the major surface to the top surface of the first semiconductor laminate.
